(19) United States
(12) Patent Application Publication
(10) Pub. No.: US 2012/0138981 A1
(43) Pub. Date: Jun. 7, 2012

(54) Light-Emitting Diode Apparatus and Method for Making the Same

(75) Inventors: Hsuen-Li Chen, Taoyuan County (TW); Shih-Liang Ku, Taoyuan County (TW); Tai-Hsiang Chen, Taoyuan County (TW); Chan-Wei Hsu, Taoyuan County (TW)

(73) Assignee: Chung-Shan Institute of Science and Technology, Armaments, Bureau, Ministry of National Defense, Taoyuan County (TW)

(21) Appl. No.: 12/958,457

(22) Filed: Dec. 2, 2010

(51) Int. Cl. H01L 33/22; H01L 33/00

(52) U.S. Cl. 257/98; 438/27; 257/E33.056; 257/E33.001

(57) ABSTRACT

A light-emitting diode apparatus includes a light-emitting diode, a first package layer provided over the light-emitting diode, and a second package layer provided over the first package layer. The first package layer is dosed with phosphor. The second package layer is not dosed with any phosphor. The second package layer is formed with a textured light-emitting surface.

### BACKGROUND OF INVENTION

1. Field of Invention

The present invention relates to a light-emitting diode apparatus and, more particularly, to a light-emitting diode apparatus that reduces total internal reflection at the interface between itself and the air.

2. Conventional Structures

There are various white light-emitting diode (“LED”) apparatuses. One of them includes a blue LED chip and a package layer dosed with yellow phosphor. The illumination efficiency of the white LED apparatus is however low because there is total internal reflection at the interface between the package layer and the air due to a difference between the refractive index of the package layer (about 1.5) and that of the air (1.0).

The present invention is therefore intended to obviate or at least alleviate the problems encountered in the conventional structures.

### SUMMARY OF INVENTION

It is the primary objective of the present invention to provide an efficient light-emitting diode apparatus that reduces total internal reflection at the interface between itself and the air.

To achieve the foregoing objective, the light-emitting diode apparatus includes a light-emitting diode, a first package layer provided over the light-emitting diode, and a second package layer provided over the first package layer. The first package layer is dosed with phosphor. The second package layer is not dosed with any phosphor. The second package layer is formed with a textured light-emitting surface.

Other objectives, advantages and features of the present invention will be apparent from the following description referring to the attached drawings.

### BRIEF DESCRIPTION OF DRAWINGS

The present invention will be described via detailed illustration of the preferred embodiment referring to the drawings wherein:

FIG. 1 is a cross-sectional view of a light-emitting diode apparatus according to a first embodiment of the present invention;

FIG. 2 is a cross-sectional view of a light-emitting diode apparatus according to a second embodiment of the present invention; and

FIGS. 3 to 11 show various steps of a method for making a light-emitting diode apparatus shown in FIG. 1 and FIG. 2.

### DETAILED DESCRIPTION OF EMBODIMENTS

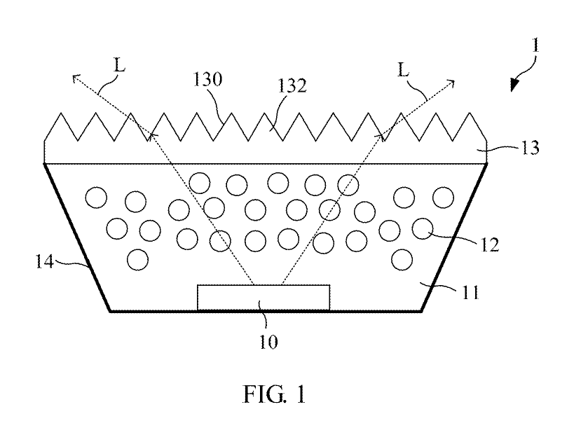

Referring to FIG. 1, a light-emitting diode (“LED”) apparatus 1 includes an LED 10, a first package layer 11, a second package layer 13 and a base 14 according to a first embodiment of the present invention. The LED 10 is located on the base 14. The base 14 is preferably in the form of a bowl for containing the LED 10.

The first package layer 11 is provided over the LED 10 and the base 14. The first package layer 11 is doped with phosphor 12. The first package layer 11 is made of epoxy or silicone for example.

The LED 10 is preferably a blue LED while the phosphor 12 is preferably yellow phosphor. The blue LED 10 casts blue light onto the yellow phosphor 12. Exited by a portion of the blue light, the yellow phosphor 12 emits yellow light. The yellow light mixes with the other portion of the blue light and together they become white light.

The refraction index of the first package layer 11 is identical to that of the second package layer 13. That is, the second package layer 13 is also made of epoxy or silicone for example. Alternatively, the refraction index of the first package layer 11 may be closed to that of the second package layer 13.

The second package layer 13 is provided over the first package layer 11. The second package layer 13 is not doped with any phosphor. The second package layer 13 preferably includes a textured light-emitting surface 130 extending thereon.

Referring to FIG. 1, the textured light-emitting surface 130 includes a plurality of protuberances 132 extending thereon. The protuberances 132 are in the form of a cone. The protuberances 132 can be in any other proper shapes. The protuberances 132 can be in a same shape or in different shapes. The protuberances 132 are in the order of hundred nanometers.

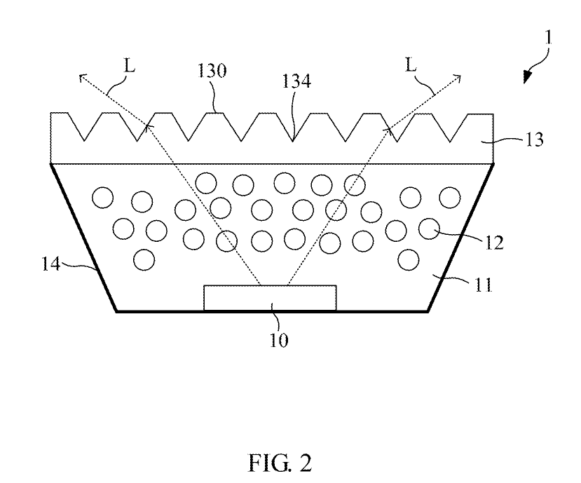

Referring to FIG. 2, there is shown an LED apparatus according to a second embodiment of the present invention. The second embodiment is like the first embodiment except that the textured light-emitting surface 130 includes a plurality of cavities 134 instead of the protuberances 132. Each of the cavities 134 is made by pressing a boss shaped like a cone into a planar surface. The cavities 134 can be in any other proper shapes. The cavities 134 can be in a same shape or in different shapes. The cavities 134 are in the order of hundred nanometers.

The LED apparatus 1 emits light L to the interface between the air and the second package layer 13, i.e., the textured light-emitting surface 130 of the second package layer 13. The textured light-emitting surface 130 reduces total internal reflection of the light L at the interface. Hence, the illumination efficiency is high.

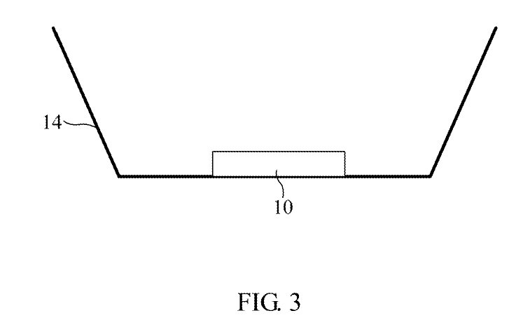

Referring to FIGS. 3 to 8, there is shown a method for making the LED apparatus 1 shown in FIG. 1. Referring to FIG. 3, the LED 10 is provided on the base 14.

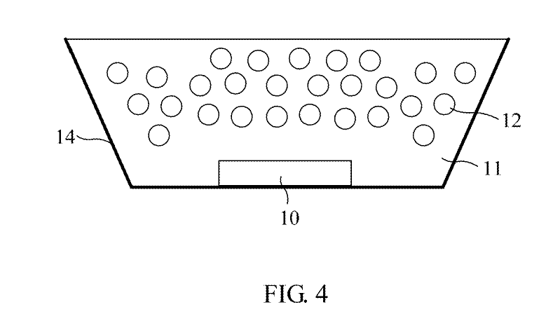

Referring to FIG. 4, the first package layer 11 is provided over the LED 10. The first package layer 11 is dosed with the phosphor 12 before the first package layer 11 is provided over the LED 10. The LED apparatus 1 is preferably a white LED apparatus. Hence, the LED 10 is preferably a blue LED while the phosphor 12 is preferably yellow phosphor.

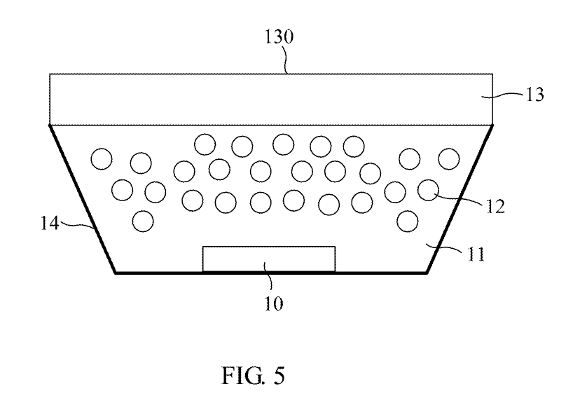

Referring to FIG. 5, the second package layer 13 is provided over the first package layer 11. The second package layer 13 is not doped with any phosphor. The second package layer 13 is preferably provided over the first package layer 11 via spin coating. Now, the second package layer 13 includes a smooth light-emitting surface.

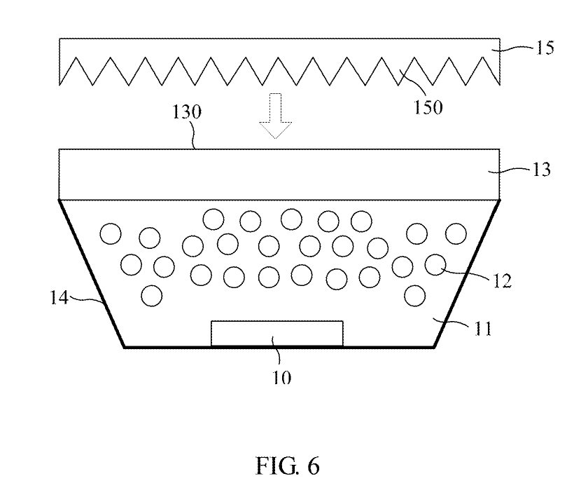

Referring to FIG. 6, there is provided a mold 15. The mold 15 includes bosses 150.

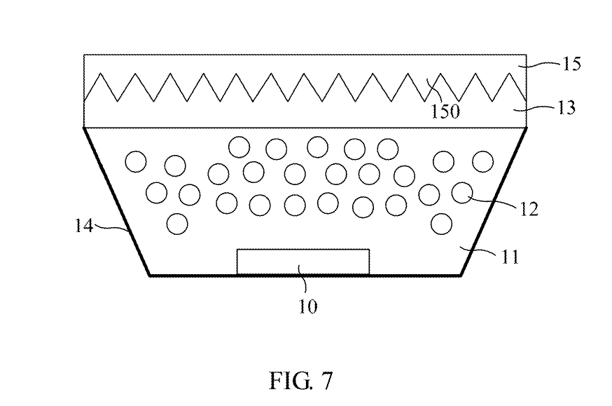

Referring to FIG. 7, the mold 15 is pressed onto the smooth light-emitting surface of the second package layer 13. The bosses 150 make dents in the second package layer 13. Portions of the second package layer 13 between the detents become the protuberances 132. The second package layer 130 is subjected to a curing process via ultraviolet light or heat for example.

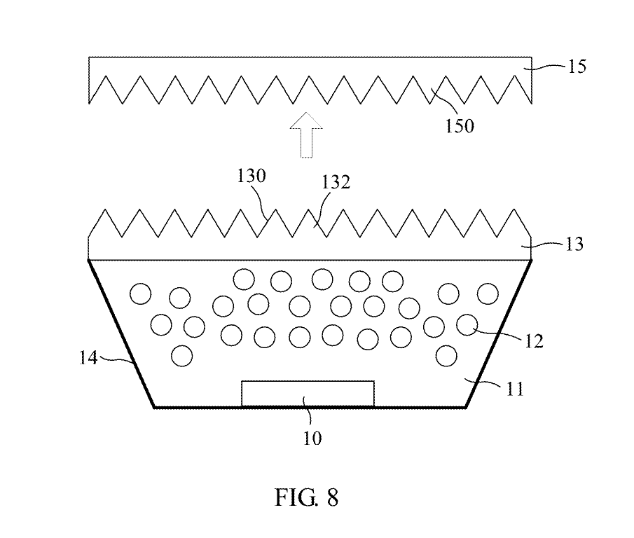

Referring to FIG. 8, the mold 15 is removed from the second package layer 13. Thus, the textured light-emitting surface 130 is made with the protuberances 132. The second package layer 13 is not doped with any phosphor because phosphor would hinder the pressing since phosphor is hard and often in the form of large particles. It is easier for the bosses 150 to make the dents in the second package layer 13 without than with phosphor. The protuberances 132 can be in the order of hundred nanometers.

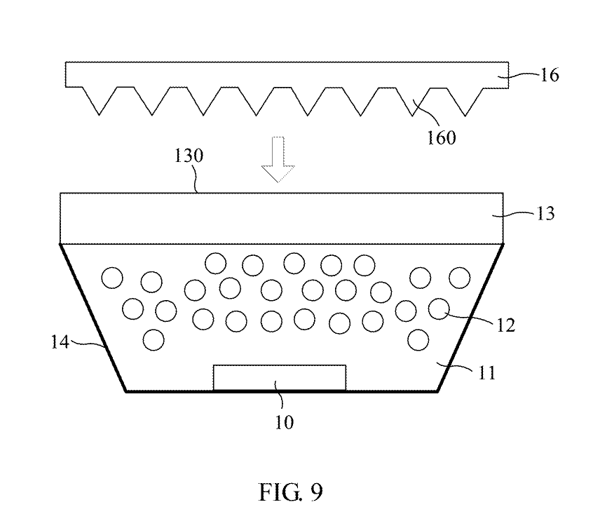

Referring to FIGS. 9 to 11, there is shown a method for making the LED apparatus 1 shown in FIG. 2. The method for making the LED apparatus 1 shown in FIG. 2 is like the method for making the LED apparatus 1 shown in FIG. 1 except using a mold 16 instead of the mold 15.

Referring to FIG. 9, the mold 16 includes bosses 160 in compliance with the cavities 134.

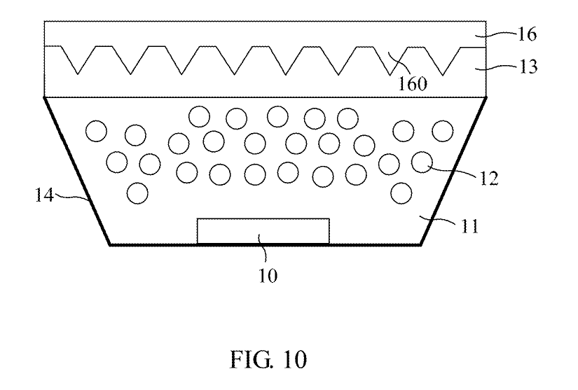

Referring to FIG. 10, the mold 16 is pressed onto the smooth light-emitting surface of the second package layer 13. Hence, the bosses 160 make the cavities 134.

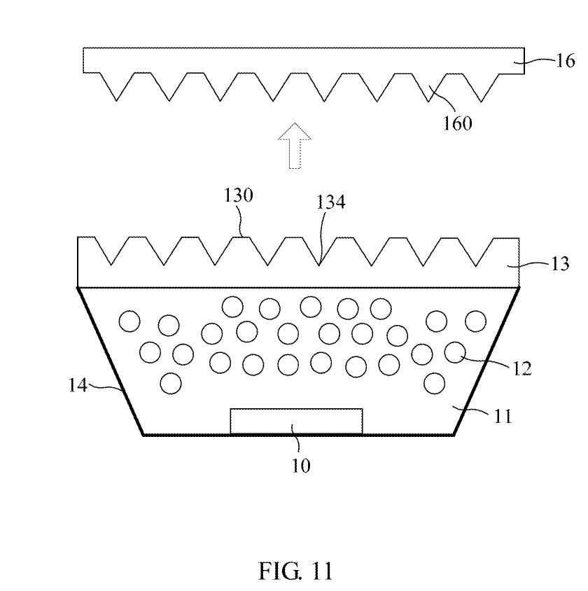

Referring to FIG. 11, the mold 16 is removed from the second package layer 13. Thus, the textured light-emitting surface 130 is made with the cavities 134.

As discussed above, the second package layer 13, which is not dosed with any phosphor, is provided over the first package layer 11 and textured. Thus, the total internal reflection at the interface between the air and the second layer package 13 is reduced. Hence, the illumination efficiency of the LED apparatus 1 is increased.

The textured light-emitting surface 130 includes many facets that become interfaces between the air and the second package layer 13. Thus, there are many incident angles for the light L. Thus, the total internal reflection is reduced. A high height-to-width or depth-to-width ratio is good for the reduction of reflected light because of the total internal reflection to be refracted again and emitted. It has been found from experiments that the illumination efficiency can be increased by 5% to 30% when the height-to-width or depth-to-width ratio is 0.5 to 5 and the distance between two adjacent protuberances or cavities is 200 nm to 5 μm.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A light-emitting diode apparatus including:
a light-emitting diode 10;
a first package layer 11 provided over the light-emitting diode 10, wherein the first package layer 11 is dosed with phosphor 12; and
a second package layer 13 provided over the first package layer 11, wherein the second package layer 13 is not dosed with any phosphor, wherein the second package layer 13 is formed with a textured light-emitting surface 130.

2. The light-emitting diode apparatus according to claim 1, wherein the textured light-emitting surface 130 includes a plurality of protuberances 132 formed thereon.

3. The light-emitting diode apparatus according to claim 2, wherein each of the protuberances 132 is in the form of a cone.

4. The light-emitting diode apparatus according to claim 1, wherein the textured light-emitting surface 130 includes a plurality of cavities 134 defined therein.

5. The light-emitting diode apparatus according to claim 4, wherein each of the cavities 134 is in compliance with a cone.

6. The light-emitting diode apparatus according to claim 1, wherein the first package layer 11 is made with a refraction index identical to that of the second package layer 13.

7. The light-emitting diode apparatus according to claim 1, wherein the first package layer 11 is made with a refraction index closed to that of the second package layer 13.

8. The light-emitting diode apparatus according to claim 1, wherein the light-emitting diode 10 is a blue light-emitting diode while the phosphor 12 is yellow phosphor.

9. The light-emitting diode apparatus according to claim 1, including a base 14 for supporting the light-emitting diode 10.

10. A method for making a light-emitting diode apparatus including the steps of:
providing a light-emitting diode 10;
providing a first package layer 11 over the light-emitting diode 10, wherein the first package layer 11 is dosed with phosphor 12; and
providing a second package layer 13 over the first package layer 11, wherein the second package layer 13 is not dosed with any phosphor, wherein the second package layer 13 is formed with a light-emitting surface 130; and
making a texture on the light-emitting surface 130 of the second package layer 13.

11. The method according to claim 10, wherein the step for making the texture on the light-emitting surface 130 of the second package layer 13 includes the steps of:
providing a mold 15, 16 with a plurality of bosses 150, 160; and
pressing the mold 15, 16 onto the light-emitting surface 130, thus making the texture.

12. The method according to claim 11, including the step of curing the light-emitting surface 130 after the step of pressing the mold 15, 16 onto the light-emitting surface 130.

13. The method according to claim 10, wherein the textured light-emitting surface 130 includes a plurality of protuberances 132 formed thereon.

14. The method according to claim 13, wherein each of the protuberances 132 is in the form of a cone.

15. The method according to claim 10, wherein the textured light-emitting surface 130 includes a plurality of cavities 134 defined therein.

16. The method according to claim 15, wherein the each of the cavities 134 is in compliance with a cone.

17. The method according to claim 10, wherein the first package layer 11 is made with a refraction index identical to that of the second package layer 13.

18. The method according to claim 10, wherein the first package layer 11 is made with a refraction index higher than that of the second package layer 13.

19. The method according to claim 10, wherein the light-emitting diode 10 is a blue light-emitting diode while the phosphor 12 is yellow phosphor.

20. The method according to claim 10, including the step of providing a base 14 for supporting the light-emitting diode 10.
